(19) United States
(12) Patent Application Publication
(10) Pub. No.: US 2026/0304994 A1
(43) Pub. Date: Oct. 1, 2026

(54) IMAGING DEVICE

(71) Applicant: SK hynix Inc., Icheon-si (KR)

(72) Inventor: Hyuk AN, Icheon-si (KR)

(21) Appl. No.: 19/633,783

(22) Filed: Mar. 30, 2026

(30) Foreign Application Priority Data
Mar. 28, 2025 (KR) 10-2025-0039929

(51) Int. Cl. H10F 39/00

(52) U.S. Cl. CPC H10F 39/811; H10F 39/802; H10F 39/8037

(57) ABSTRACT

Disclosed is an imaging device including a pixel region and a non-pixel region around the pixel region, including: a first insulating layer disposed in the pixel region and the non-pixel region; a second insulating layer disposed on the first insulating layer and comprising a plurality of first grooves in the pixel region; a first connecting portion disposed in the first groove in the second insulating layer; a floating diffusion region disposed in the first groove and on the first connecting portion; and a substrate portion disposed on the second insulating layer and the floating diffusion region and comprising a photodetector disposed in the pixel region, and the floating diffusion region may protrude in a downward direction from a lower surface of the substrate portion.

### CROSS-REFERENCE TO RELATED APPLICATION(S)

This patent document claims priority to Korea Patent Application No. 10-2025-0039929, filed on Mar. 28, 2025, the disclosure of which is incorporated herein for all purposes by this reference.

### TECHNICAL FIELD

Embodiments of the disclosed technology relate to an imaging device.

### BACKGROUND

Recently, with the development of information and communication technologies and the digitalization of the electronic devices, the image sensors with improved performance are used in various fields, such as a digital camera, a camcorder, a mobile phone, a personal communication system (PCS), a game machine, a security camera and a medical micro camera. In general, the image sensor may include a pixel region which includes a photodiode and a peripheral circuit region. A unit pixel may include a photodiode and a transmission transistor. The transmission transistor may be disposed between the photodiode and a floating diffusion region and may transfer charges generated by the photodiode to the floating diffusion region.

### SUMMARY

Various implementations of the disclosed technology provide an imaging device capable of operating in a high conversion gain (HCG) mode.

Various implementations of the disclosed technology provide an imaging device capable of reducing a capacitance in the floating diffusion region.

In one aspect, an imaging device comprises: a pixel region that includes a photodetector that detects incident light to produce photocharge representative of the detected incident light, and a floating diffusion region to store the produced photocharge from the photodetector; a non-pixel region disposed around the pixel region; a first insulating layer disposed in the pixel region and the non-pixel region; a second insulating layer disposed on the first insulating layer and comprising a plurality of first grooves in the pixel region; a first connecting portion disposed in a first groove of the plurality of first grooves in the second insulating layer, wherein the floating diffusion region is disposed on the first connecting portion and in the first groove of the second insulating layer; and a substrate disposed on the second insulating layer and comprising the photodetector in the pixel region, the substrate having a first surface and a second surface that is opposite the first surface and closer to the floating diffusion region than the first surface, wherein the floating diffusion region in the second insulating layer protrudes in a direction away from the second surface of the substrate.

In another aspect, an imaging device comprises: a photodetector disposed in a pixel region and generating photocharges in response to incident light; a floating diffusion region disposed in the pixel region and storing the photocharges from the photodetector; and a semiconductor region disposed in the pixel region and operating as an electrode of a transmission transistor for transferring the photocharges generated by the photodetector to the floating diffusion region, wherein a width of the floating diffusion region is smaller than a width of the semiconductor region.

Other details of the embodiments are included in the detailed description and the accompanying drawings.

According to embodiments of the disclosed technology, it is possible to minimize a contact area between the floating diffusion region and the first connecting portion by forming the floating diffusion region to protrude downward from the substrate portion, thereby being able to reduce a capacitance of the floating diffusion region and operate in the high conversion gain (HCG) mode.

According to embodiments of the disclosed technology, it is possible to operate in the high conversion gain (HCG) mode by increasing a spacing distance between the floating diffusion region and a gate electrode of a transistor adjacent thereto so as to reduce the capacitance of the floating diffusion region.

The effects of the disclosed technology are not limited to the above-described effects and other effects which are not described herein may be clearly understood by those skilled in the art from the following description of the embodiments of the disclosed technology.

### BRIEF DESCRIPTION OF THE DRAWINGS

FIG. 1 is an example of a block diagram illustrating an imaging system based on an embodiment of the disclosed technology.

FIG. 2 is an example of a diagram illustrating an image sensing device illustrated in FIG. 1 based on an embodiment of the disclosed technology.

FIG. 3 is an example of a block diagram of an image sensing device in FIG. 1 based on an embodiment of the disclosed technology.

FIG. 4 is an example of a circuit diagram of a pixel of a pixel array in FIG. 3 based on an embodiment of the disclosed technology.

FIG. 5 is an example of a plan view of a pixel array based on an embodiment of the disclosed technology.

FIG. 6 is a cross-sectional view taken along A-A′ line in FIG. 5.

FIG. 7 is a cross-sectional view taken along B-B′ line in FIG. 5.

FIG. 8 is a cross-sectional view illustrating a capacitance of a floating diffusion region in a cross-sectional view in FIG. 5.

FIG. 9 is a cross-sectional view illustrating a capacitance in a floating diffusion region in a cross-sectional view in FIG. 6.

FIGS. 10 to 16 are cross-sectional views illustrating an example of a method for manufacturing a pixel array at various stages of manufacture based on an embodiment of the disclosed technology.

### DETAILED DESCRIPTION

Hereinafter, certain specific examples of the embodiments and/or implementations of the imaging device technology are described with reference to the accompanying drawings.

Like reference numerals refer to like elements throughout. Additionally, in the drawings, the thicknesses, proportions, and dimensions of components may be exaggerated for ease of description and clarity. The term “and/or” includes any and all combinations of one or more of the associated listed items.

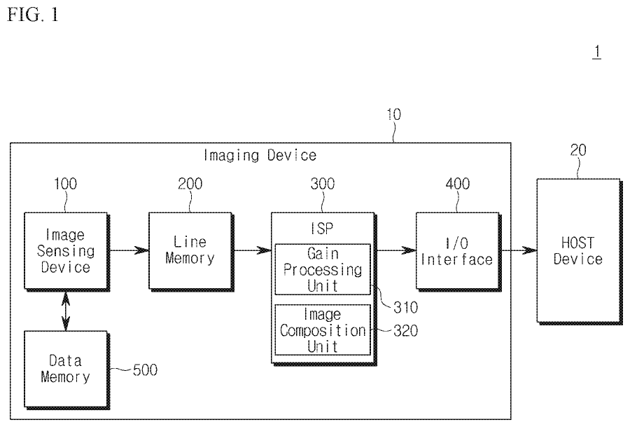

FIG. 1 is an example of a block diagram illustrating an imaging system based on an embodiment of the disclosed technology.

Referring to FIG. 1, an imaging system 1 may mean not only a device for photographing still images or video, but also a device configured to detect a motion. For example, the imaging device 10 may be implemented as a Digital Single Lens Reflex (DSLR) camera, a mirrorless camera, or a mobile phone (in particular, a smartphone), but is not limited thereto. The imaging device 10 may be a concept of a device having a lens and an image pickup element such that the device can capture a target object and can, thus, create an image of the target object.

The imaging system 1 may include the imaging device 10 and a host device 20.

The imaging device 10 may include an image sensing device 100, a line memory 200, an image signal processor (ISP) 300, an I/O interface 400, and a data memory 500.

In some implementations, the image sensing device 100 may be a CIS (Complementary Metal Oxide Semiconductor Image Sensor) configured to convert an optical signal into an electric signal. The overall operations such as turning on/off, operation modes, operation timings, sensitivity, and the likes of the image sensing device 100 may be controlled by the ISP 300. The sensitivity of a pixel in the image sensing unit 100 refers to its ability to convert incident light into an electrical signal. In the example, the amount of increase in image data over light exposure time in the pixel is based on the sensitivity of the pixel. The image sensing device 100 may transmit image data obtained by converting an optical signal into an electric signal to the line memory 200 based on the control of the ISP 300.

The line memory 200 may include a volatile memory (e.g., a DRAM, an SRAM) and/or a non-volatile memory (e.g., a flash memory).

The line memory 200 may receive image data from the image sensing device 100, store the received image data, and transmit the stored image data to the ISP 300 according to the control of the ISP 300.

The ISP 300 may perform image signal processing of the image data stored in the line memory 200. The ISP 300 may reduce noise of image data, and may perform image signal processing such as gamma correction, color filter array interpolation, color matrix, color correction, color enhancement, lens distortion correction, etc. for image-quality improvement.

In order to generate the HDR image, the ISP 300 may include a gain processing unit 310, and an image compositing unit 320.

The gain processing unit 310 may determine a gain to be calculated to (for example, multiplication) image data. The gain processing unit 310 may determine a gain according to a difference in the conversion gain between an HCG (high conversion gain) mode and an LCG (low conversion gain) mode, and provide the determined gain to the image compositing unit 320.

Each pixel of the pixel array 110 may operate in one among the HCG mode and the LCG mode, and a mode of each pixel may be determined by intensity of light (or illuminance) incident to each pixel.

The image compositing unit 320 may synthesize HDR image corresponding to a high dynamic range by using the image data of the pixel operating in the HCG mode and/or the image data of the pixel operating in the LCG mode.

The ISP 300 may transmit image data (e.g., HDR image) obtained through such image signal processing to the I/O interface 400.

According to another embodiment, the gain processing unit 310 and the image compositing unit 320 for generation of an HDR image may be included in the image sensing device 100, rather than the ISP 300.

The I/O interface 400 may perform communication with the host device 20, and may transmit image data obtained through the image signal processing to the host device 20.

The host device 20 may include a processor configured to process the image data obtained through the image signal processing and received from the imaging device 10 (for example, an application processor), a memory configured to store image data (for example, a non-volatile memory), or a display device configured to visually output image data (for example, a liquid crystal display (LCD)).

The data memory 500 may store image data Data_PX in a digital format which is converted by an analog-to-digital converter 140.

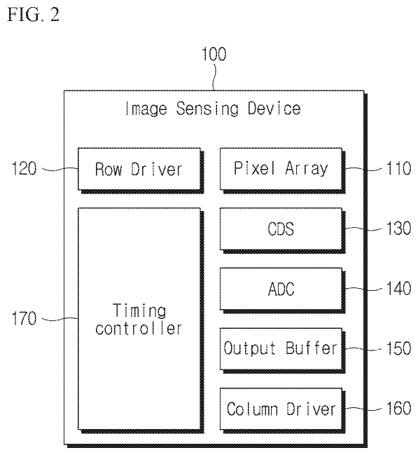

FIG. 2 is an example of a diagram illustrating the image sensing device illustrated in FIG. 1 based on some implementations of the disclosed technology.

Referring to FIG. 2, the image sensing device 100 may include a pixel array 110, a row driver 120, a CDS (Correlate Double Sampler) 130, an ADC (Analog-Digital Converter) 140, an output buffer 150, a column driver 160, and a timing controller 170. Here, each component of the image sensing device 100 is only illustrative, and at least some component may be added or omitted as needed.

The pixel array 110 may include a plurality of image pixels SP disposed in a plurality of rows and a plurality of columns. In an embodiment, the plurality of image pixels SP may be disposed in a two-dimensional pixel array which includes rows and columns. In another example, the plurality of image pixels SP may be arranged in a three-dimensional pixel array. The plurality of image pixels SP may convert an optical signal into an electrical signal on a unit pixel basis or a pixel group basis, and the pixels in the pixel group may share at least some of an internal circuit. The pixel array 110 may receive pixel control signals, including a row selection signal, a pixel reset signal and a transmission signal, from the row driver 120, and upon receiving the pixel control signals, corresponding pixels in the pixel array 110 may be activated to perform the operations corresponding to the row selection signal, the pixel reset signal and the transmission signal. Each of the image pixels SP may generate photocharges corresponding to the intensity of incident light (or illuminance), and may generate an electrical signal having a magnitude corresponding to the amount of the generated photocharges, thereby sensing the incident light. For convenience of description, the image pixel may be referred to as a pixel as well.

The row driver 120 may activate the pixel array 110 such that the pixels SP included in the corresponding row perform certain operations based on the commands and the control signals provided by the timing controller 170.

In an embodiment, the CDS 130 may sequentially sample and hold the reference signal and the image signal, which are provided to each of a plurality of column lines from the pixel array 110. That is, the CDS 130 may sample and hold levels of the reference signal and the image signal corresponding to each of the columns of the pixel array 110.

The CDS 130 may transfer the reference signal and the image signal of each of the columns as a correlate double sampling signal to the ADC 140 based on a control signal from the timing controller 170.

The ADC 140 may convert the correlate double sampling signal output from the CDS 130 with respect to each column into digital signals, and output the image data. In an embodiment, the ADC 140 may convert the correlate double sampling signal generated by the CDS 130 for each of the columns into digital signals, and output the digital signals.

The ADC 140 may include a plurality of column counters corresponding to columns of the pixel array 110, respectively. Each of the columns of the pixel array 110 may be connected to each column counter, and the image data may be generated using the column counter by converting the correlate double sampling signal corresponding to each of the columns into a digital signal.

The output buffer 150 may temporarily hold the column-based image data provided from the ADC 140 and may output the image data. The output buffer 150 may temporarily store image data output from the ADC 140 based on the control signal of the timing controller 170.

The column driver 160 may select a column of the output buffer 150 based on a control signal from the timing controller 170, and may control the output buffer 150 to sequentially output the image data, which is temporarily stored in the selected column of the output buffer 150.

The timing controller 170 may control at least one among the row driver 120, the CDS 130, the ADC 140, the output buffer 150 and the column driver 160.

The timing controller 170 may provide at least one among the row driver 120, the CDS 130, the ADC 140, the output buffer 150 and the column driver 160 with a clock signal required for the operation of each component of the image sensing device 100, a control signal for timing control, and address signals for selecting a row or a column. According to an embodiment, the timing controller 170 may include a logic control circuit, a phase lock loop (PLL) circuit, a timing control circuit, and a communication interface circuit, etc.

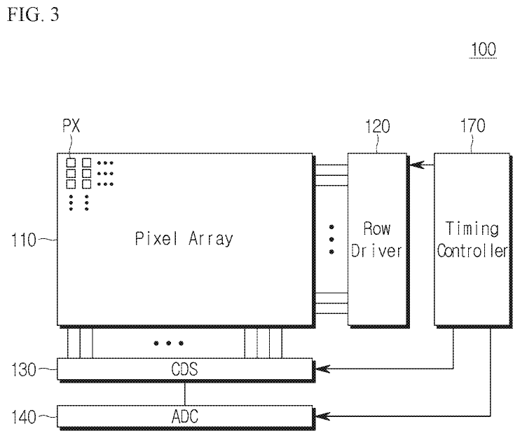

FIG. 3 is an example of a block diagram of the image sensing device in FIG. 1.

Referring to FIG. 3, the pixel array 110 may include the plurality of pixels PX that detect incident light to capture an image in the detected incident light. The pixels PX may be arranged in a matrix form along a row direction and a column direction, however the embodiments of the present disclosure are not limited thereto. The pixels PX may include a red pixel that selectively detects red light, a green pixel that selectively detects green light, and a blue pixel that selectively detects blue light, however the embodiments of the present disclosure are not limited thereto, and the pixels PX may further include a white pixel or an infrared light pixel.

The plurality of pixels PX may be electrically connected to the row driver 120.

The timing controller 170, the CDS 130, and the ADC 140 illustrated in FIG. 3 have been described in FIG. 2, and therefore, redundant description thereof will be omitted.

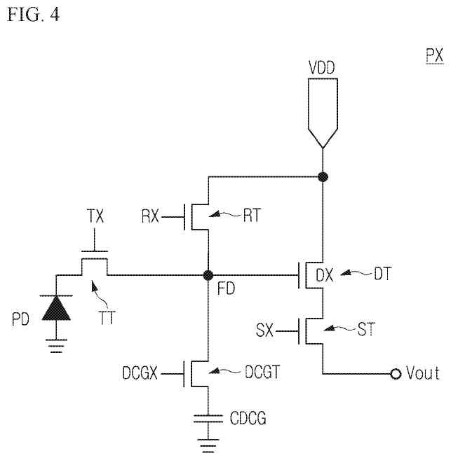

FIG. 4 is an example of a circuit diagram of the pixel of the pixel array in FIG. 3 based on an embodiment of the disclosed technology.

Referring to FIG. 4, the circuit diagram of the pixel may correspond to an equivalent circuit of each pixel PX included in the pixel array (refer to 110 in FIG. 3).

The pixel PX may include the photodetector PD, the transmission transistor TT, the reset transistor RT, the floating diffusion region FD, a driver transistor DT, a selection transistor ST, and a DCG (dual conversion gain) transistor. That is, the pixel may have a structure of a 5TR (5 -transistor) pixel.

The photodetector PD may generate and accumulate photocharges corresponding to the intensity of the incident light. For example, the photodetector PD may be implemented as a photo diode, a photo transistor, a photo gate, a pinned photo diode, or a combination thereof. When the photodetector PD is implemented as a photo diode, it may be a region doped with impurities of a second conductive type (for example, an n-type) in the substrate portion having a first conductive type (for example, a p-type).

The transmission transistor TT may be connected between the photodetector PD and the floating diffusion region FD. The transmission transistor TT may be turned on or off in response to a transmission signal TX applied to the gate electrode, and the transmission transistor TT which is turned on may transfer the photocharges accumulated in the photodetector PD to the floating diffusion region FD to be stored in the floating diffusion region FD for readout by operations performed by the driver transistor DT, the selection transistor ST, the DCG (dual conversion gain) transistor and the reset transistor RT as further explained below. A source electrode of the transmission transistor TT may be connected to the photodetector PD, and a drain electrode thereof may be connected to the floating diffusion region FD.

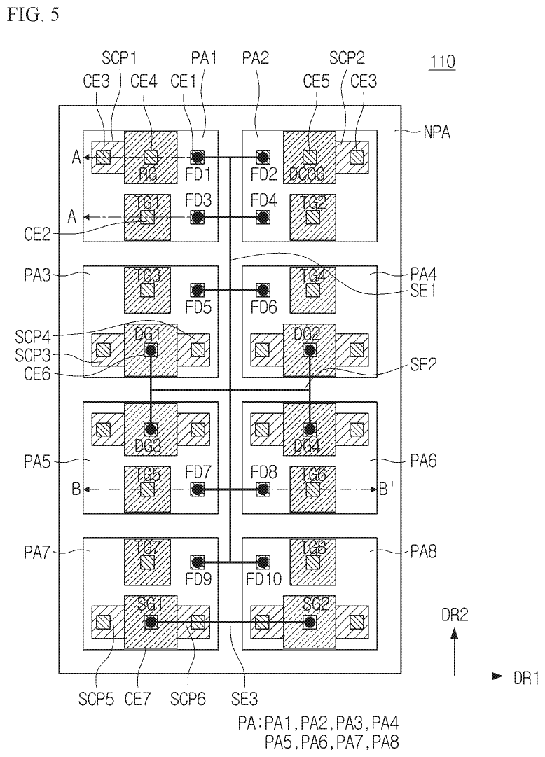

In FIG. 4, it is illustrated that one transmission transistor TT is connected to the floating diffusion region FD, however, a plurality of transmission transistors TT may be connected to the floating diffusion region FD. In this case, a plurality of photodetectors PD may be connected to the floating diffusion region FD through the plurality of transmission transistors TT. Each pixel PX may include one photodetector PD and one transmission transistor TT connected to the photodetector. In some implementations, the transmission transistors TT of the plurality of pixels PX may be shared in one floating diffusion region FD. In FIG. 5, a structure in which eight transmission transistors TT are connected to the floating diffusion region FD is illustrated.

The reset transistor RT may be connected between a power supply voltage VDD and the floating diffusion region FD, and may reset a voltage of the floating diffusion region FD to the power supply voltage VDD after a readout operation in response to the pixel reset signal RX applied to the gate electrode so that the floating diffusion region FD is ready to receive newly generated photocharge from one or more photodetectors PDs. The power supply voltage VDD may be applied to a source electrode of the reset transistor RT, and a drain electrode of the reset transistor RT may be connected to the floating diffusion region FD.

The floating diffusion region FD may accumulate photocharges that are produced by one or more photodetectors PDs and are transferred from the transmission transistor TT. For example, the floating diffusion region FD may be a region doped with impurities of a second conductive type (for example, the n-type) on the substrate portion having a first conductive type (for example, the p-type), and the substrate portion and the impurity-doped region may be modeled as a junction capacitor. The floating diffusion region FD may be connected to a gate electrode of the driver transistor DT, a drain electrode of the transmission transistor TT, and a drain electrode of the DCG transistor DCGT. In FIG. 4, the floating diffusion region FD of only one pixel PX is illustrated, however, the floating diffusion regions FD of the plurality of pixels PX may be electrically connected (or shared) with one another. In FIG. 5, a structure in which the floating diffusion regions of eight pixels PX are shared is illustrated.

The driving transistor DT may be connected between the power supply voltage VDD and the selection transistor ST, may amplify an electric potential change of the floating diffusion region FD, which has received the photocharges accumulated in the photodetector PD, and transfer the photocharges to the selection transistor ST for readout in form of a pixel signal Vout. A gate electrode of the driving transistor DT may be connected to the floating diffusion region FD, the power supply voltage VDD may be applied to a source electrode of the driving transistor DT, and a drain electrode thereof may be connected to a source electrode of the selection transistor ST. In FIG. 4, the driver transistor DT of only one pixel PX is illustrated, however, the driver transistors DT of the plurality of pixels PX may be electrically connected (or shared) with one another. In FIG. 5, a structure in which the driver transistors DT of four pixels PX are shared is illustrated.

The selection transistor ST may be connected between the driver transistor DT and an output signal line VOL (or a column line), be turned on by a row selection signal SX applied to the gate electrode, and output an electric signal transferred from the driver transistor DT as a pixel signal Vout. The source electrode of the selection transistor ST may be connected to a drain electrode of the driver transistor DT. In FIG. 4, the selection transistor ST of only one pixel PX is illustrated, however, the selection transistors ST of the plurality of pixels PX may be electrically connected (or shared) with one another. In FIG. 5, a structure in which the selection transistors ST of two pixels PX are shared is illustrated.

A DCG signal DCGX may be applied to a gate electrode of the DCG transistor DCGT, a source electrode thereof may be connected to a DCG capacitor CDCG, and a drain electrode thereof may be connected to the floating diffusion region FD. As illustrated in FIG. 3, the transistors TT, RT, DT, DCGT and ST may be implemented as an NMOS (N-channel Metal oxide Semiconductor) transistor, however, they are not limited thereto, and may be implemented as a PMOS (P-channel Metal oxide Semiconductor) transistors.

The DCG transistor DCGT may be turned on or off in response to the DCG signal DCGX applied to the gate electrode. The DCG transistor DCGT may be turned off or on according to the HCG mode and the LCG mode. For example, in the HCG mode, the DCG transistor DCGT may be turned off, and in the LCG mode, the DCG transistor DCGT may be turned on.

A voltage of the floating diffusion region FD may be determined based on an amount of photocharges transferred through the transmission transistor TT, and as the amount of the photocharges is great, the voltage of the floating diffusion region FD may be lowered.

The DCG transistor DCGT may provide a parasitic capacitance of the DCG transistor DCGT of its own to the floating diffusion region FD, and the DCG transistor DCGT which is turned on may provide a capacitance of the DCG capacitor CDCG to the floating diffusion region additionally.

Each of the transmission signal TX, the pixel reset signal RX, the row selection signal SX, and the DCG signal DCGX may be supplied from the row driver 120, but the embodiments are not limited thereto.

FIG. 5 is an example of a plan view of the pixel array based on an embodiment of the disclosed technology. As further discussed below, FIG. 5 illustrates a shared pixel structure where multiple pixels share floating diffusion regions, driver transistors, and selection transistors via shared electrodes SE1, SE2, and SE3.

Referring to FIGS. 4 and 5, the pixel array 110 according to an embodiment may include the plurality of pixels (refer to PX in FIG. 4), each pixel PX may include a pixel region (one among PA1 to PA8) and a non-pixel region NPA which surrounds the pixel region (one among PA1 to PA8). In FIG. 5, the non-pixel region NPA is disposed between the pixel regions PA1 to PA8 and surrounds each pixel region PA1 to PA8. FIG. 5 illustrates eight pixel regions PA1 to PA8 since those eight pixel regions PA1 to PA8 share the floating diffusion regions (refer to FD in FIG. 4). However, other implementations are also possible. For example, the number of the floating diffusion regions, the number of the driver transistors, and the number of the selection transistors which are electrically connected to one another can vary across different implementations.

The transmission transistor TT in FIG. 4 may include the transmission transistors (first to eighth transmission transistors) disposed in each of a first pixel region PA1 to an eighth pixel region PA8, and the driver transistor DT in FIG. 4 may include the driver transistor (first to the fourth driver transistors) disposed in each of a third pixel region PA3 to the eighth pixel region PA8, and the floating diffusion region FD in FIG. 3 may include the floating diffusion region (first to eighth floating diffusion regions) disposed in each of the first pixel region PA1 to the eighth pixel region PA8.

In the first pixel region PA1, a gate electrode RG of the reset transistor RT, a gate electrode TG1 of the first transmission transistor, a first semiconductor region SCP1, a first connecting portion CE1, a third connecting portion CE3, a fourth connecting portion CE4, a first floating diffusion region FD1, and a third floating diffusion region FD3 may be disposed. The first connecting portion CE1, the third connecting portion CE3, the fourth connecting portion CE4, and the connecting portions which will be described may include a conductive material. An example of the conductive material may be metal.

The gate electrode RG and the fourth connecting portion CE4 may overlap each other, the first semiconductor region SCP1 and the third connecting portion CE3 may overlap each other, the gate electrode TG1 and the second connecting portion CE2 may overlap each other, and the floating diffusion regions FD1 and FD3 and the first connecting portion CE1 may overlap each other. The positions of the gate electrode RG of the reset transistor RT, the gate electrode TG1 of the first transmission transistor, the first semiconductor region SCP1, the first connecting portion CE1, the third connecting portion CE3, the fourth connecting portion CE4, the first floating diffusion region FD1, and the third floating diffusion region FD3 illustrated in FIG. 5 may be changed. Hereinafter, a connecting portion overlapping the gate electrodes TG1 to TG8 of the first to eighth transmission transistors which have been described above will be defined as the second connecting portion CE2, a connecting portion overlapping the first to eighth floating diffusion regions FD1 to FD8 will be defined as the first connecting portion CE1, and a connecting portion overlapping the first to sixth semiconductor regions SCP1 to SCP6 which will be described below will be defined as the third connecting portion CE3.

The first semiconductor region SCP1 to the sixth semiconductor region SCP6 may be or include regions doped with impurities of the second conductive type (for example, the n-type). The first to eighth floating diffusion regions FD1 to FD8 may be regions doped with impurities of the second conductive type (for example, the n-type).

The first semiconductor region SCP1 may be a source electrode of the transmission transistor RT, and the power supply voltage VDD may be applied to the first semiconductor region SCP1, however, the embodiments of the present disclosure are not limited thereto.

In a second pixel region PA2, the gate electrode DCGG of the DCG transistor DCGT, a fifth connecting portion CE5, a second semiconductor region SCP2, the third connecting portion CE3, a gate electrode TG2 of the second transmission transistor, a second floating diffusion region FD2, and a fourth floating diffusion region FD4 may be disposed.

The gate electrode DCGG and the fifth connecting portion CE5 may overlap each other, the gate electrode TG2 and the second connecting portion CE2 may overlap each other, and the second semiconductor region SCP2 and the third connecting portion CE3 may overlap each other.

The second semiconductor region SCP2 may be a source region of the DCG transistor DCGT, and may be electrically connected to the DCG capacitor CDCG.

In the third pixel region PA3, a gate electrode DG1 of a first driver transistor, a sixth connecting portion CE6, a third semiconductor region SCP3, a fourth semiconductor region SCP4, the third connecting portion CE3, a gate electrode TG3 of the third transmission transistor, and a fifth floating diffusion region FD5 may be disposed. A connecting portion overlapping the gate electrodes DG1, DG2, DG3 and DG4 of the first to fourth driver transistors may be defined as the sixth connecting portion CE6, and a source region and a drain region (or a drain region and a source region) of the first to fourth driver transistors will be defined as the third semiconductor region SCP3 and the fourth semiconductor region SCP4, respectively.

The gate electrode DG1 and the sixth connecting portion CE6 may overlap each other, the gate electrode TG3 and the second connecting portion CE2 may overlap each other, and each of the third semiconductor region SCP3 and the fourth semiconductor region SCP4 and the third connecting portion CE3 may overlap each other.

One among the third semiconductor region SCP3 and the fourth semiconductor region SCP4 may be a source region of the driver transistor, and a remaining other may be a drain region of the driver transistor.

In a fourth pixel region PA4, a gate electrode DG2 of a second driver transistor, the sixth connecting portion CE6, the third semiconductor region SCP3, the fourth semiconductor region SCP4, the third connecting portion CE3, a gate electrode TG4 of the fourth transmission transistor, and a sixth floating diffusion region FD6 may be disposed.

The gate electrode DG2 and the sixth floating diffusion region FD6 may overlap each other, the gate electrode TG4 and the second connecting portion CE2 may overlap each other, and each of the third semiconductor region SCP3 and the fourth semiconductor region SCP4 and the second connecting portion CE2 may overlap each other.

In a fifth pixel region PA5, a gate electrode DG3 of a third driver transistor, the sixth connecting portion CE6, the third semiconductor region SCP3, the fourth semiconductor region SCP4, the third connecting portion CE3, a gate electrode TG5 of a fifth transmission transistor, and a seventh floating diffusion region FD7 may be disposed.

The gate electrode DG3 and the sixth connecting portion CE6 may overlap each other, the gate electrode TG5 and the second connecting portion CE2 may overlap each other, and each of the third semiconductor region SCP3 and the fourth semiconductor region SCP4 and the second connecting portion CE2 may overlap each other.

In a sixth pixel region PA6, a gate electrodes DG4 of the fourth driver transistor, the sixth connecting portion CE6, the third semiconductor region SCP3, the fourth semiconductor region SCP4, the third connecting portion CE3, a gate electrode TG6 of a sixth transmission transistor, and the eighth floating diffusion region FD8 may be disposed.

The gate electrode DG4 and the sixth connecting portion CE6 may overlap each other, the gate electrode TG6 and the second connecting portion CE2 may overlap each other, and each of the third semiconductor region SCP3 and the fourth semiconductor region SCP4 and the second connecting portion CE2 may overlap each other.

In a seventh pixel region PA7, a gate electrode SG1 of a first selection transistor, a seventh connecting portion CE7, a fifth semiconductor region SCP5, the sixth semiconductor region SCP6, the third connecting portion CE3, a gate electrode TG7 of a seventh transmission transistor, and a ninth floating diffusion region FD9 may be disposed.

The gate electrode SG1 and the seventh connecting portion CE7 may overlap each other, the gate electrode TG7 and the second connecting portion CE2 may overlap each other, and each of the fifth semiconductor region SCP5 and the sixth semiconductor region SCP6 and the second connecting portion CE2 may overlap each other. One among the fifth semiconductor region SCP5 and the sixth semiconductor region SCP6 may be a source region of the selection transistor, and a remaining other may be a drain region of the selection transistor.

In the eighth pixel region PA8, a gate electrode SG2 of a second selection transistor, the seventh connecting portion CE7, the fifth semiconductor region SCP5, the sixth semiconductor region SCP6, the third connecting portion CE3, a gate electrode TG8 of the eighth transmission transistor, and a tenth floating diffusion region FD10 may be disposed.

The gate electrode SG2 and the seventh connecting portion CE7 may overlap each other, the gate electrode TG8 and the second connecting portion CE2 may overlap each other, and each of the fifth semiconductor region SCP5 and the sixth semiconductor region SCP6 and the second connecting portion CE2 may overlap each other.

As described above, the first to tenth floating diffusion regions FD1 to FD10 may be electrically connected to one another. For example, the first to tenth floating diffusion regions FD1 to FD10 may be electrically connected to one another through a first shared electrode SE1.

In some implementations, the first to fourth driver transistors may be electrically connected to one another through a second shared electrode SE2.

In some implementations, the first and second selection transistors may be electrically connected to each other through a third shared electrode SE3. Hereinafter, a cross-sectional structure of the pixel array will be described.

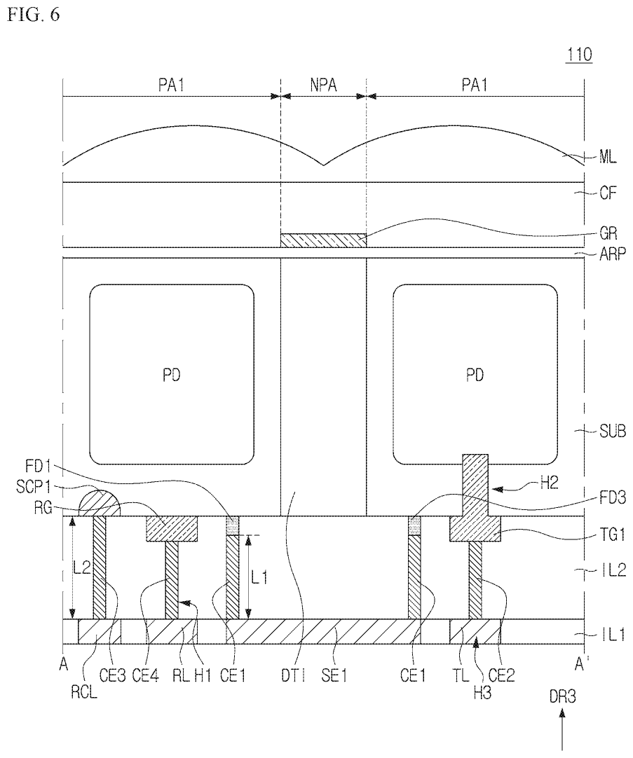

FIG. 6 is a cross-sectional view taken along A-A′ line in FIG. 5.

Referring to FIG. 5 and FIG. 6, the pixel array 110 according to an embodiment may include the circuit portion, the substrate portion SUB on the circuit portion, an antireflective layer ARP on the substrate portion SUB, a grid portion GR on the antireflective layer ARP, a color filter CF on the grid portion GR, and a micro lens ML on the color filter CF.

The circuit portion may be disposed on a lower surface of the substrate portion SUB, and may include transistors, a wiring layer, and an inter-layer insulating layer. The substrate portion SUB has a first surface and a second surface that is opposite the first surface and closer to the floating diffusion region than the first surface. The lower surface may refer to the second surface of the substrate portion SUB. The circuit portion may include a first insulating layer IL1, an electrode or an electric wire disposed in the third groove H3 formed on the first insulating layer IL1, a second insulating layer IL2, and a connecting portion or an electrode disposed in the second groove H2 of the second insulating layer IL2. The second groove H2 extends to the substrate portion SUB.

The first insulating layer IL1 may include a plurality of third grooves H3. The third grooves H3 may completely penetrate the first insulating layer IL1 from a lower surface to an upper surface. For example, a reset source line RCL and a reset control line RL may be disposed in the third grooves H3 in the first pixel region PA1 at the left, while a transmission control line TL may be disposed in the third grooves H3 in the first pixel region PA1 at the right. In the first pixel region PA1 at the left and the first pixel region PA1 at the right, the first shared electrode SE1 may be disposed in the third groove H3.

The second insulating layer IL2 may include a plurality of first grooves H1. The first groove H1 may completely penetrate the second insulating layer IL2 from a lower surface to an upper surface. For example, the first connecting portion CE1, the third connecting portion CE3, and the fourth connecting portion CE4 may be disposed in the first grooves in the first pixel region PA1 at the left, while the first connecting portion CE1 and the second connecting portion CE2 may be disposed in the first grooves H1 in the first pixel region PA1 at the right.

The first connecting portion CE1 at the left and the first connecting portion CE1 at the right, which are disposed in the second insulating layer IL2, may be electrically connected to the first shared electrode SE1 disposed in the first insulating layer IL1 and may be in direct contact with the first shared electrode SE1. The third connecting portion CE3 may overlap the reset source line RCL, and may be in direct contact with and electrically connected to the reset source line RCL. The fourth connecting portion CE4 may overlap the reset control line RL, may be in direct contact with and electrically connected to the reset control line RL. The second connecting portion CE2 may overlap the transmission control line TL, and may be in direct contact with and electrically connected to the transmission control line TL.

A length L1 of the first connecting portion CE1 in a third direction DR3 may be smaller than a length L2 of the third connecting portion CE3 in the third direction DR3. In some implementations, an upper surface of the second connecting portion CE2 may be positioned on the same line as an upper surface of the second insulating layer IL2. In some other implementations, the upper surface of the second connecting portion CE2 may be positioned on the same line as the upper surface of the second insulating layer IL2. For example, in FIG. 6, the upper surface of the second connecting portion CE2 may be positioned below the upper surface of the second insulating layer IL2.

The gate electrode RG of the reset transistor may be disposed on the fourth connecting portion CE4. An upper surface of the gate electrode RG may be positioned on the same line as the upper surface of the second insulating layer IL2, but the embodiments of the present disclosure are not limited thereto.

The first floating diffusion region FD1 may be disposed on the first connecting portion CE1. The first floating diffusion region FD1 may be directly disposed on the first connecting portion CE1, and may be electrically connected to the first connecting portion CE1. An upper surface of the first floating diffusion region FD1 may be positioned on the same line as the upper surface of the second insulating layer IL2, but the embodiments of the present disclosure are not limited thereto. In the example as shown in FIG. 6, the floating diffusion regions FD1 and FD3 extend from the lower surface of the substrate portion SUB in a downward direction. In this case, the floating diffusion regions FD1 and FD3 protrude in a downward direction from the lower surface of the substrate portion SUB. A width of the first floating diffusion region FD1 may be the same as a width of the first connecting portion CE1.

The gate electrode TG1 of the first transmission transistor may be disposed on the second connecting portion CE2. The second connecting portion CE2 and the gate electrode TG1 may be in direct contact with and electrically connected to each other. The gate electrode TG1 may extend further in the third direction DR3 from the second insulating layer IL2 (penetrating the second groove H2 of the substrate portion SUB), and may be in direct contact with the substrate portion SUB and the photodetector PD. That is, as the gate electrode TG1 partially overlaps the photodetector PD, transmission of the photocharges generated from the photodetector PD can be made easier.

The first semiconductor region SCP1 may be disposed on the third connecting portion CE3. The first semiconductor region SCP1 may be directly disposed on the third connecting portion CE3, and may be electrically connected to the third connecting portion CE3. A width of the first semiconductor region SCP1 may be greater than the width of the first floating diffusion region FD1. A cross-sectional shape of the first semiconductor region SCP1 may be a semi-circle, or a semi-oval, but the embodiments of the present disclosure are not limited thereto. The first semiconductor region SCP1 may be formed in a manner of partially recessing the substrate portion SUB.

The substrate portion SUB may be disposed on the second insulating layer IL2, and the connecting portions CE1, CE2 and CE3. The substrate portion SUB may include silicon Si, and for example, may have the first conductive type (for example, the p-type). The photodetector PD may be disposed in the substrate portion SUB, and may have the second conductive type (for example, the n-type).

An isolation part DTI may be disposed in the non-pixel region NPA. The isolation part DTI may completely penetrate the substrate portion SUB, however, the embodiments of the disclosed technology are not limited thereto. The isolation part DTI may be formed in a deep trench isolation manner. The isolation part DTI may include an insulating material and/or a material having conductivity. For example, examples of the insulating material may include hafnium oxide (HfOx), silicon oxide (SiOx), or tantalum oxide (TaOx), however, the embodiments of the disclosed technology are not limited thereto. Examples of the material having conductivity may include polysilicon, however, the embodiments of the present disclosure are not limited thereto. For example, the isolation part DTI may have a structure in which the material having conductivity is sandwiched between the insulating materials, however, the embodiments of the present disclosure are not limited thereto.

The antireflective layer ARP may be disposed on an upper surface of the substrate portion SUB. The antireflective layer ARP may include at least one insulating material, and may include, for example, hafnium oxide (HfOx), silicon oxide (SiOx), or tantalum oxide (TaOx), however, the embodiments of the present disclosure are not limited thereto. The antireflective layer ARP may serve to not reflect light which has passed through the color filter CF and make the light enter the substrate portion SUB.

In the non-pixel region NPA, the grid portion GR may be disposed on an upper surface of the antireflective layer ARP. The grid portion GR may absorb or reflect light incident to the grid portion GR. The grid portion GR may prevent color mixing of light between adjacent pixel regions. The grid portion GR may include a light absorbing material, or a low refractive layer. For example, when the grid portion GR includes the light absorbing material, the grid portion GR may include a metal material. The metal material may include tungsten W, however, the embodiments of the present disclosure are not limited thereto. For example, when the grid portion GR includes the low refractive layer, the grid portion GR may include a low refractive insulating material, or an air structure.

The color filter CF may be disposed on the antireflective layer ARP and the grid portion GR on the upper surface of the substrate portion SUB. The color filter CF may include a red color filter, a green color filter, or a blue color filter. In some embodiments, the color filter CF may further include a white color filter.

The micro lens ML may be disposed on the color filter CF. The micro lens ML may serve to make light incident from the outside to concentrate to the pixel regions LPX and RPX. To this end, the micro lens ML may have a shape of a convex lens which is convex upward, and may be formed of a material which has a great gap in a refractive index compared to outside air. For example, the refractive index of the micro lens ML may be about 1.5 to about 1.7, however, the embodiments of the present disclosure are not limited thereto.

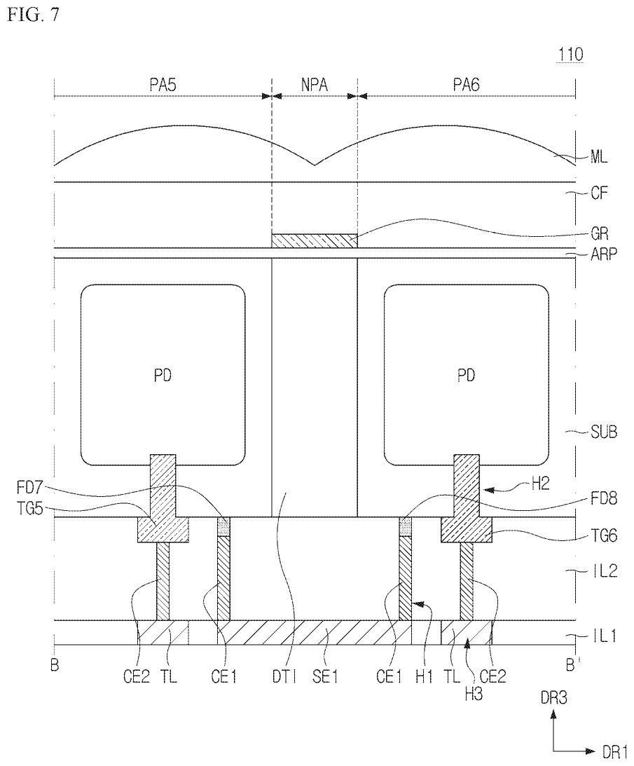

FIG. 7 is a cross-sectional view taken along B-B′ line in FIG. 5. Redundant description on the components which have been described referring to FIG. 6 will be omitted.

Referring to FIGS. 5 and 7, the first insulating layer IL1 of the pixel array 110 according to an embodiment may include the plurality of third grooves H3. The third groove H3 may completely penetrate the first insulating layer IL1 from a lower surface to an upper surface. For example, a transmission control line TL may be disposed in the third groove H3 in a fifth pixel region PA5, and the transmission control line TL may be disposed in the third groove H3 in a sixth pixel region PA6. In the fifth pixel region PA5 and the sixth pixel region PA6, the first shared electrode SE1 may be disposed in the third groove H3.

The second insulating layer IL2 may include the plurality of first grooves H1. The first groove H1 may completely penetrate the second insulating layer IL2 from a lower surface to an upper surface. For example, the first connecting portion CE1 and the second connecting portion CE2 may be disposed in the first groove H1 in the fifth pixel region PA5, and the first connecting portion CE1 and the second connecting portion CE2 may be disposed in the first groove H1 in the sixth pixel region PA6.

The second connecting portion CE2 may overlap the transmission control line TL therebelow and may be in direct contact with and electrically connected to the transmission control line TL. In the present disclosure, each of the first connecting portion CE1 at the left and the first connecting portion CE1 at the right may be in direct contact with and electrically connected to the first shared electrode SE1 therebelow.

The seventh floating diffusion region FD7 may be disposed on the first connecting portion CE1 in the fifth pixel region PA5, and the seventh floating diffusion region FD7 may be directly disposed on the first connecting portion CE1 and electrically connected to the first connecting portion CE1. The eighth floating diffusion region FD8 may be disposed on the first connecting portion CE1 in the sixth pixel region PA6. The eighth floating diffusion region FD8 may be directly disposed on the first connecting portion CE1 and electrically connected to first connecting portion CE1.

An upper surface of the seventh floating diffusion region FD7 may be positioned on the same line as the upper surface of the second insulating layer IL2, but the embodiments of the present disclosure are not limited thereto. A width of the seventh floating diffusion region FD7 may be the same as the width of the first connecting portion CE1. An upper surface of the eighth floating diffusion region FD8 may be positioned on the same line as the upper surface of the second insulating layer IL2, but the embodiments of the present disclosure are not limited thereto. In the example as shown in FIG. 7, the floating diffusion regions FD7 and FD8 extend from the lower surface of the substrate portion SUB in a downward direction. In this case, the floating diffusion regions FD7 and FD8 protrude in a downward direction from the lower surface of the substrate portion SUB. A width of the eighth floating diffusion region FD8 may be the same as the width of the first connecting portion CE1.

The gate electrode TG5 of the fifth transmission transistor may be disposed on the second connecting portion CE2. The gate electrode TG5 may be directly disposed on the second connecting portion CE2, and electrically connected to the second connecting portion CE2. The gate electrode TG5 may extend further in the third direction DR3 from the second insulating layer IL2 (penetrating the second groove H2 of the substrate portion SUB), and may be in direct contact with the substrate portion SUB and the photodetector PD. The gate electrode TG6 of the sixth transmission transistor may be disposed on the second connecting portion CE2. The gate electrode TG6 may be directly disposed on the second connecting portion CE2, and electrically connected to the second connecting portion CE2. The gate electrode TG6 may extend further in the third direction DR3 from the second insulating layer IL2 (penetrating the second groove H2 of the substrate portion SUB), and may be in direct contact with the substrate portion SUB and the photodetector PD.

The substrate portion SUB may be disposed on the second insulating layer IL2 and the connecting portions CE1 and CE2.

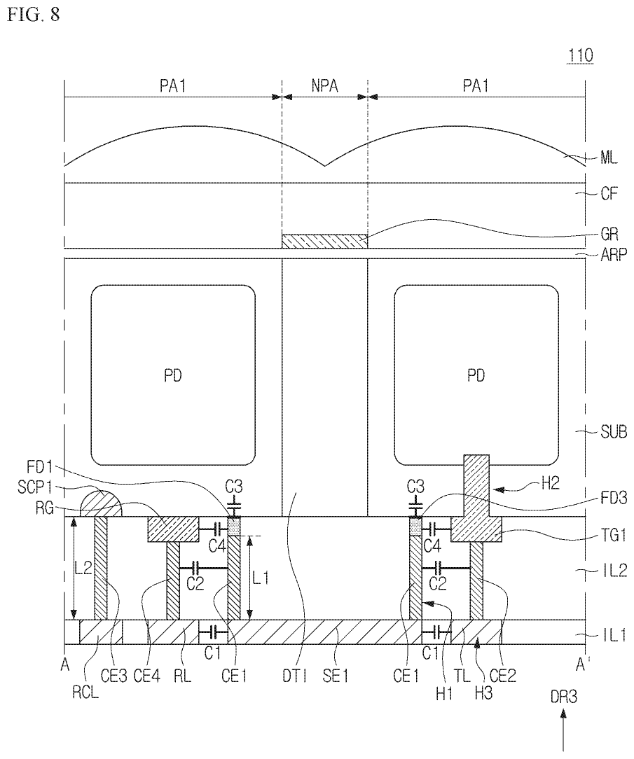

FIG. 8 is a cross-sectional view illustrating a capacitance of the floating diffusion region in the cross-sectional view in FIG. 5. In FIG. 8, only the capacitance of the floating diffusion region formed in the first pixel region PA1 (or the first pixel) is illustrated, however, as described above, the floating diffusion regions of the first to eighth pixel regions (refer to PA1 to PA8 in FIG. 5) are shared through the first shared electrode SE1, and thus, the capacitance can be understood as a capacitance formed in the floating diffusion regions of the eight pixel regions PA1 to PA8.

The capacitance formed in the floating diffusion region of the pixel array 110 may include a capacitance of the DCG capacitor CDCG when the DCG transistor DCGT is turned on. Hereinafter, for convenience of description, description on the DCG capacitor CDCG will be omitted.

The capacitance formed in the floating diffusion region of the pixel array 110 may be a sum of a first capacitance C1 between the first shared electrode SE1 and a line RL and TL adjacent thereto, a second capacitance C2 between the first connecting portion CE1 and the connecting portion CE2 and CE4 adjacent thereto, a third capacitance C3 between the floating diffusion region FD1 and FD3 and the substrate portion SUB, and a fourth capacitance C4 between the floating diffusion region FD1 and FD3 and the gate electrode RG and TG1.

According to the pixel array 110 according to an embodiment, as the floating diffusion regions FD1 and FD3 are inserted into the second groove H2 of the second insulating layer IL2, it is possible to design a width of the floating diffusion region FD1 and FD3 to be the same as a width of the connecting portion CE1. With this configuration, the third capacitance C3 may be reduced by decreasing an area in which the floating diffusion region FD1 and FD3 and the substrate portion SUB are in contact with each other.

Further, as the width of the floating diffusion region FD1 and FD3 is designed to be the same as the width of the connecting portion CE1, a spacing distance between the floating diffusion region FD1 and FD3 and the gate electrode RG and TG1 adjacent thereto may increase, thereby it becomes possible to reduce the fourth capacitance C4.

Thus, according to the pixel array 110 according to an embodiment, as the third and fourth capacitances C3 and C4 are lowered, the capacitance formed in the floating diffusion region as a whole can be lowered, and as a result, it is possible to provide the imaging device capable of operating in the HCG mode.

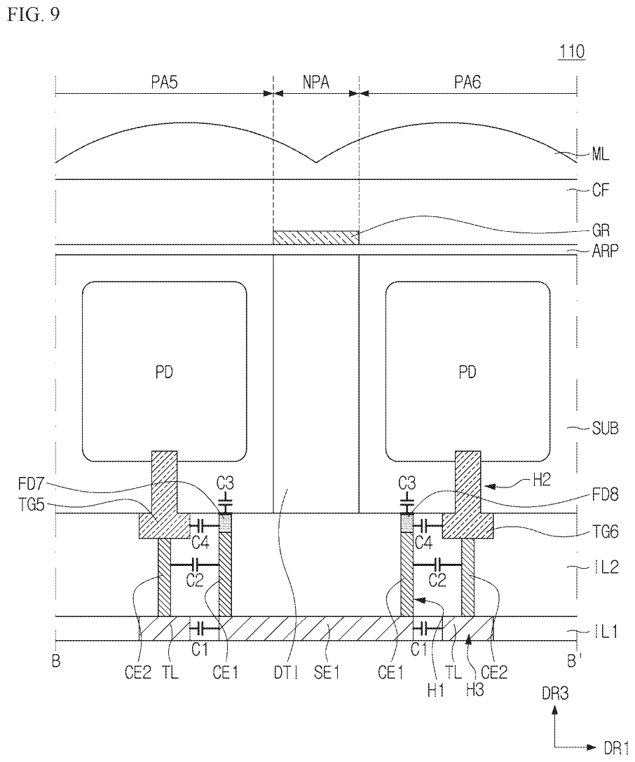

FIG. 9 is a cross-sectional view illustrating the capacitance in the floating diffusion region in the cross-sectional view in FIG. 6.

In FIG. 9, only the capacitances of the floating diffusion regions formed in the fifth pixel region PA5 (or the fifth pixel) and the sixth pixel region PA6 (or the sixth pixel) are illustrated, however, as described above, the floating diffusion regions of the first to eighth pixel regions (refer to PA1 to PA8 in FIG. 5) are shared through the first shared electrode SE1, and thus, the capacitance has to be understood as a capacitance formed in the floating diffusion regions of the eight pixel regions PA1 to PA8.

The capacitance formed in the floating diffusion region of the pixel array 110 may be a sum of a first capacitance C1 between the first shared electrode SE1 and a line TL adjacent thereto, a second capacitance C2 between the first connecting portion CE1 and the second connecting portion CE2 adjacent thereto, a third capacitance C3 between the floating diffusion region FD7 and FD8 and the substrate portion SUB, and a fourth capacitance C4 between the floating diffusion region FD7 and FD8 and the gate electrode TG5 and TG6.

According to the pixel array 110 according to an embodiment, as the floating diffusion regions FD7 and FD8 are inserted into the second groove H2 of the second insulating layer IL2, it is possible to design a width of the floating diffusion region FD7 and FD8 to be the same as a width of the connecting portion CE1. With this configuration, the third capacitance 3 may be reduced by decreasing an area in which the floating diffusion region FD7 and FD8 and the substrate portion SUB are in contact with each other.

Further, as the width of the floating diffusion region FD7 and FD8 is designed to be the same as the width of the connecting portion CE1, a spacing distance between the floating diffusion region FD7 and FD8 and the gate electrode TG5 and TG6 adjacent thereto may increase, thereby it becomes possible to reduce the fourth capacitance C4.

Thus, according to the pixel array 110 according to an embodiment, as the third and fourth capacitances C3 and C4 are lowered, the capacitance formed in the floating diffusion region as a whole can be lowered, and as a result, it is possible to provide the imaging device capable of operating in the HCG mode.

Hereinafter, a method for manufacturing the imaging device according to an embodiment will be described. Redundant description on the components which have been described referring to FIGS. 1 to 9 will be omitted.

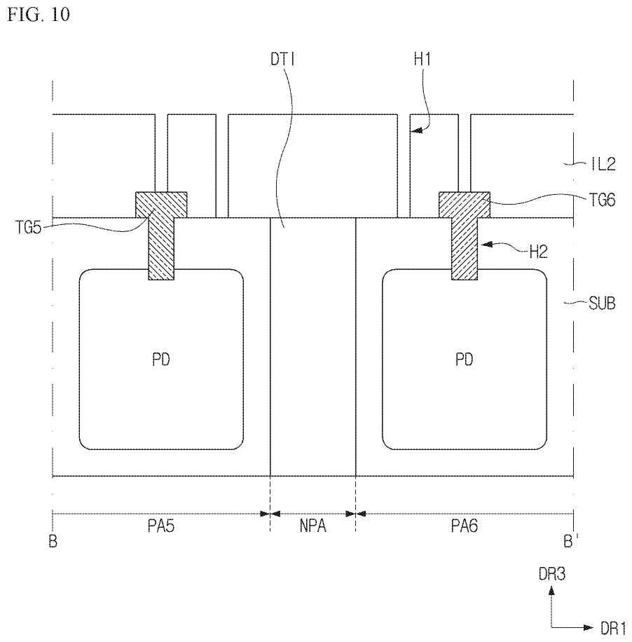

FIGS. 10 to 16 are cross-sectional views illustrating a method for manufacturing the pixel array according to an embodiment at various stages of manufacture. FIGS. 10 to 16 illustrate a cross-sectional structure of the example of the pixel array in FIG. 7, however, the method for manufacturing the pixel array described in FIGS. 10 to 16 may be applied in the same way to the cross-sectional structure of the pixel array in FIG. 6 as well. FIGS. 10 to 16 illustrate the pixel array based on a state in which the cross-sectional structure in FIG. 7 is inverted in the vertical direction for convenience of description.

Referring to FIGS. 7 and 10, the first groove H1 is formed in the second insulating layer IL2. The first groove H1 may overlap the fifth and the sixth pixel regions PA5 and PA6.

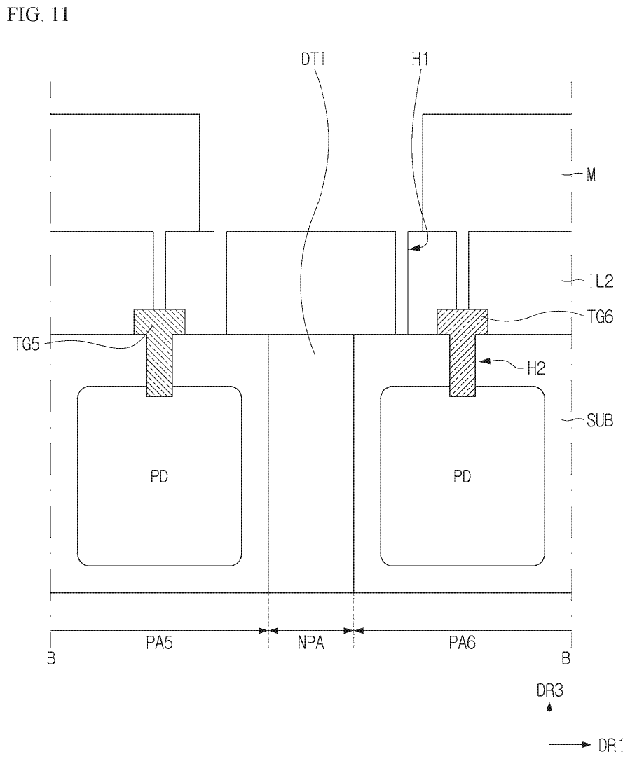

Next, referring to FIGS. 7 and 11, a mask M is disposed on the second insulating layer IL2 such that a position in which the floating diffusion region FD7 and FD8 is formed is exposed. The mask M may be a photoresist, however, the embodiments of the disclosed technology are not limited thereto.

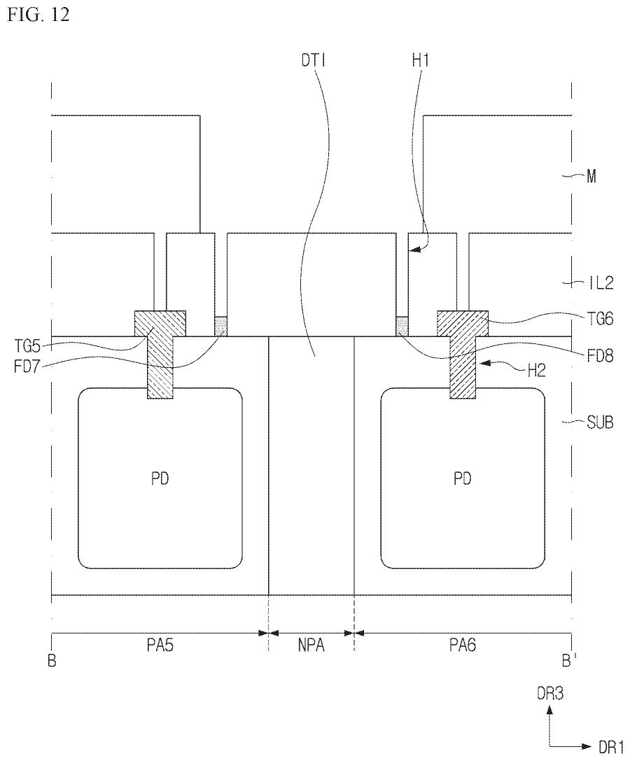

Next, referring to FIGS. 7 and 12, the floating diffusion region FD7 and FD8 is grown and formed from a surface of the substrate portion SUB in the first groove H1. The floating diffusion region FD7 and FD8 may be a region doped with impurities of the second conductive type (for example, the n-type). A width of the floating diffusion region FD7 and FD8 may be the same as a width of the first groove H1.

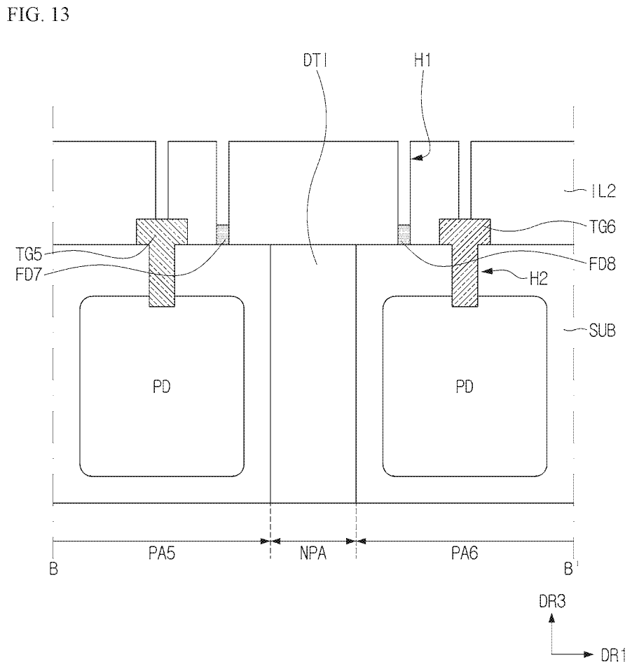

Next, referring to FIGS. 7 and 13, the mask M in FIG. 12 is removed. A process for removing the mask M may be a strip process of the mask M, and after removing the mask M, a cleaning process may be performed additionally.

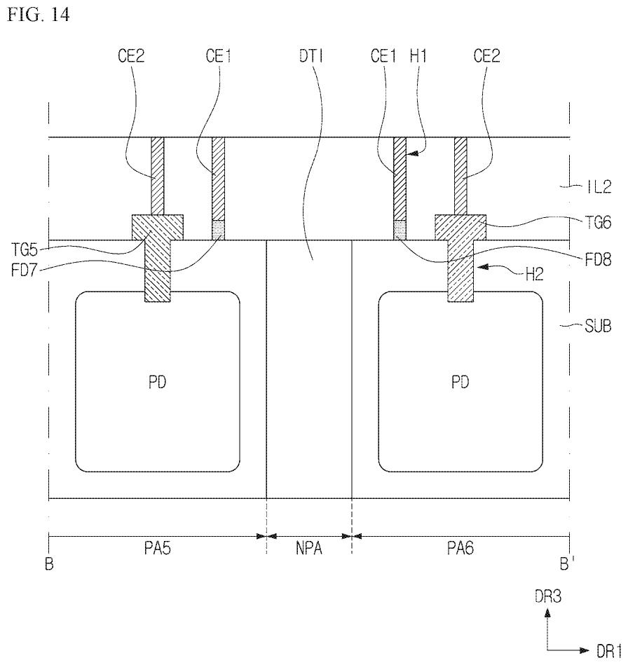

Next, referring to FIGS. 7 and 14, the connecting portion CE1 and CE2 is formed in the first grooves H1. A width of the first connecting portion CE1 and the second connecting portion CE2 may be the same, however, the embodiments of the disclosed technology are not limited thereto.

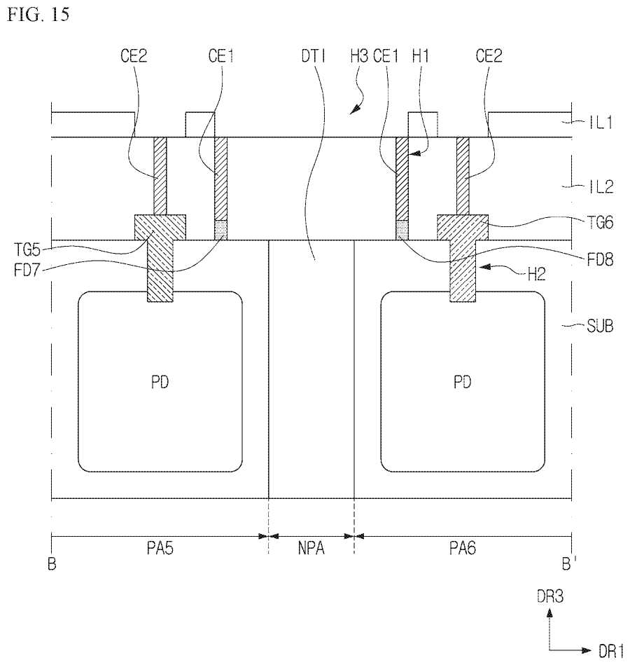

Next, referring to FIGS. 7 and 15, the first insulating layer IL1 is formed on the second insulating layer IL2. The first insulating layer IL1 may include the plurality of third grooves H3, and the third groove H3 may correspond to and overlap the transmission control line TL and the first shared electrode SE1 in FIG. 7.

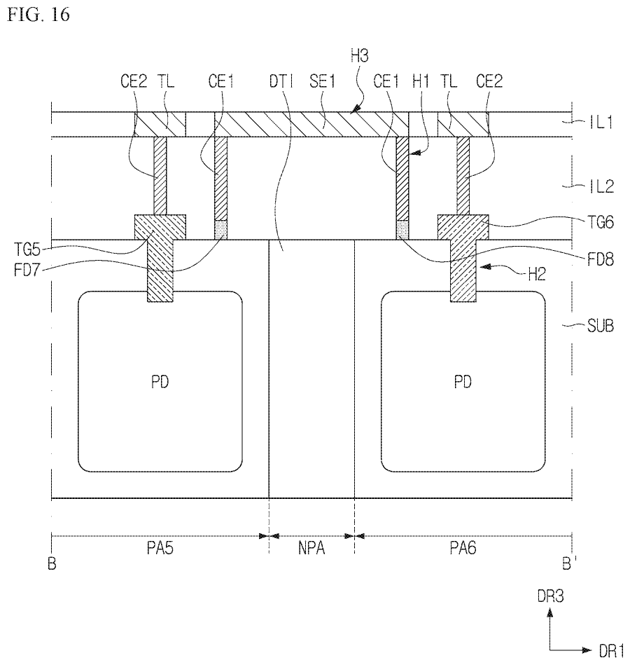

Next, referring to FIGS. 7 and 16, the transmission control line TL and the first shared electrode SE1 are formed in the third grooves H3, respectively.

The imaging device according to various embodiments of the disclosed technology may be described as below.

One embodiment is an imaging device including a pixel region and a non-pixel region around the pixel region, including: a first insulating layer disposed in the pixel region and the non-pixel region; a second insulating layer disposed on the first insulating layer and comprising a plurality of first grooves in the pixel region; a first connecting portion disposed in the first groove in the second insulating layer; a floating diffusion region disposed in the first groove on the first connecting portion; and a substrate portion disposed on the second insulating layer and the floating diffusion region and comprising a photodetector disposed in the pixel region, and the floating diffusion region may protrude in a downward direction from a lower surface of the substrate portion.

According to the imaging device according to various embodiments of the disclosed technology, the floating diffusion region may be in direct contact with the substrate portion.

According to the imaging device according to various embodiments of the disclosed technology, a capacitance may be formed between the floating diffusion region and the substrate portion.

According to the imaging device according to various embodiments of the disclosed technology, a width of the floating diffusion region may be identical to a width of the first connecting portion.

According to the imaging device according to various embodiments of the disclosed technology, the floating diffusion region may be a p-type and the substrate portion may be an n-type.

According to the imaging device according to various embodiments of the disclosed technology, the imaging device may further include: a second connecting portion disposed in the first groove of the second insulating layer and a gate electrode on the second connecting portion.

According to the imaging device according to various embodiments of the disclosed technology, the gate electrode may be a gate electrode of a transmission transistor, a reset transistor, a selection transistor or a DCG transistor.

According to the imaging device according to various embodiments of the disclosed technology, a capacitance may be formed between the floating diffusion region and the gate electrode, and between the first connecting portion and the second connecting portion.

According to the imaging device according to various embodiments of the disclosed technology, the imaging device may further include: a third connecting portion disposed in the first groove of the second insulating layer and a semiconductor region on the third connecting portion, and a length of the third connecting portion may be greater than a length of the first connecting portion.

According to the imaging device according to various embodiments of the disclosed technology, an upper surface of the third connecting portion may be positioned on a same line as an upper surface of the second insulating layer.

According to the imaging device according to various embodiments of the disclosed technology, a width of the floating diffusion region may be smaller than a width of the semiconductor region.

According to the imaging device according to various embodiments of the disclosed technology, a lower surface of the semiconductor region may be in direct contact with an upper surface of the second insulating layer.

According to the imaging device according to various embodiments of the disclosed technology, the pixel region may include: a first pixel region; and a second pixel region adjacent to the first pixel region, and the floating diffusion region of the first pixel region and the floating diffusion region of the second pixel region may be electrically connected to each other through a shared electrode disposed in a third groove of the first insulating layer.

Another embodiment is an imaging device including a plurality of pixel regions and a non-pixel region disposed between the pixel regions adjacent to each other, including: a photodetector disposed in the pixel region; a floating diffusion region disposed in the pixel region; and a semiconductor region disposed in the pixel region, and a width of the floating diffusion region may be smaller than a width of the semiconductor region.

According to the imaging device according to various embodiments of the disclosed technology, the pixel region may include: a first pixel region; and a second pixel region adjacent to the first pixel region, and the floating diffusion region of the first pixel region and the floating diffusion region of the second pixel region may be electrically connected to each other through a shared electrode disposed in a third groove of the first insulating layer.

According to the imaging device according to various embodiments of the disclosed technology, the imaging device may further include: a first insulating layer disposed in the pixel region and the non-pixel region; a second insulating layer disposed on the first insulating layer and comprising a plurality of first grooves in the pixel region; and the floating diffusion region disposed in the first groove of the second insulating layer.

According to the imaging device according to various embodiments of the disclosed technology, the imaging device may further include: a first connecting portion disposed below the floating diffusion region in the first groove, and the first connecting portion may include a conductive material.

According to the imaging device according to various embodiments of the disclosed technology, an upper surface of the floating diffusion region may be positioned on a same line as an upper surface of the second insulating layer.

According to the imaging device according to various embodiments of disclosed technology, the imaging device may further include: a second connecting portion disposed in the first groove, and a lower surface of the semiconductor region may be in direct contact with an a lower surface of the second insulating layer.

According to the imaging device according to various embodiments of the disclosed technology, each of the floating diffusion region and the semiconductor region may be a p-type.

The embodiments of the present disclosure have been described with reference to accompanying drawings. Those of ordinary skill in the art will recognize that the present disclosure may be embodied in other various forms. Only a few implementations and examples are described and other implementations, enhancements and variations can be made based on what is described and illustrated in this patent document.

I/We claim:

1. An imaging device, comprising:
a pixel region that includes a photodetector that detects incident light to produce photocharge representative of the detected incident light, and a floating diffusion region to store the produced photocharge from the photodetector;
a non-pixel region disposed around the pixel region;
a first insulating layer disposed in the pixel region and the non-pixel region;
a second insulating layer disposed on the first insulating layer and comprising a plurality of first grooves in the pixel region;
a first connecting portion disposed in a first groove of the plurality of first grooves in the second insulating layer, wherein the floating diffusion region is disposed on the first connecting portion and in the first groove of the second insulating layer; and
a substrate disposed on the second insulating layer and comprising the photodetector in the pixel region, the substrate having a first surface and a second surface that is opposite the first surface and closer to the floating diffusion region than the first surface,
wherein the floating diffusion region in the second insulating layer protrudes in a direction away from the second surface of the substrate.

2. The imaging device of claim 1,
wherein the floating diffusion region is in direct contact with the substrate.

3. The imaging device of claim 2,
wherein a capacitance is formed between the floating diffusion region and the substrate.

4. The imaging device of claim 1,
wherein a width of the floating diffusion region is identical to a width of the first connecting portion.

5. The imaging device of claim 1,
wherein the floating diffusion region is a p-type and the substrate is an n-type.

6. The imaging device of claim 1, further comprising:
a second connecting portion disposed in a first groove of the plurality of first grooves of the second insulating layer and a gate electrode disposed on the second connecting portion.

7. The imaging device of claim 6, wherein the gate electrode is a gate electrode of a transmission transistor, a reset transistor, a selection transistor or a DCG transistor.

8. The imaging device of claim 6,
wherein a capacitance is formed between the floating diffusion region and the gate electrode, and between the first connecting portion and the second connecting portion.

9. The imaging device of claim 1, further comprising:
a third connecting portion disposed in a first groove of the plurality of first grooves of the second insulating layer and a semiconductor region on the third connecting portion,
wherein a length of the third connecting portion is greater than a length of the first connecting portion.

10. The imaging device of claim 9,
wherein a surface of the third connecting portion is positioned on a same line as a surface of the second insulating layer.

11. The imaging device of claim 9,
wherein a width of the floating diffusion region is smaller than a width of the semiconductor region.

12. The imaging device of claim 9,
wherein a surface of the semiconductor region is in direct contact with a surface of the second insulating layer.

13. The imaging device of claim 1,
wherein the floating diffusion region is disposed in a first pixel region of the pixel region, and
wherein the floating diffusion region of the first pixel region and a floating diffusion region of a second pixel region adjacent to the first pixel region are electrically connected to each other through a shared electrode disposed in a third groove of the first insulating layer.

14. An imaging device, comprising:
a photodetector disposed in a pixel region and generating photocharges in response to incident light;
a floating diffusion region disposed in the pixel region and storing the photocharges from the photodetector; and
a semiconductor region disposed in the pixel region and operating as an electrode of a transmission transistor for transferring the photocharges generated by the photodetector to the floating diffusion region,
wherein a width of the floating diffusion region is smaller than a width of the semiconductor region.

15. The imaging device of claim 14,
wherein the floating diffusion region is disposed in a first pixel region, and
wherein the floating diffusion region of the first pixel region and a floating diffusion region of a second pixel region adjacent to the first pixel region are electrically connected to each other through a shared electrode disposed in a third groove of a first insulating layer.

16. The imaging device of claim 14, further comprising:
a first insulating layer disposed in the pixel region and a non-pixel region disposed around the pixel region; and
a second insulating layer disposed on the first insulating layer and comprising a plurality of first grooves in the pixel region,
wherein the floating diffusion region is disposed in a first groove of the plurality of first grooves of the second insulating layer.

17. The imaging device of claim 16, further comprising:
a first connecting portion disposed below the floating diffusion region in the first groove,
wherein the first connecting portion comprises a conductive material.

18. The imaging device of claim 16,
wherein a surface of the floating diffusion region is positioned on a same line as a surface of the second insulating layer.

19. The imaging device of claim 16, further comprising:
a second connecting portion disposed in a first groove of the plurality of first grooves,
wherein a surface of the semiconductor region is in direct contact with a surface of the second insulating layer.

20. The imaging device of claim 14,
wherein each of the floating diffusion region and the semiconductor region has impurities doped with a p-type.
